(19) United States
(12) Patent Application Publication
(10) Pub. No.: US 2026/0173821 A1
(43) Pub. Date: Jun. 18, 2026

(54) ZT STAGE

(71) Applicant: INNO ROBOTICS INC., Hwaseong-si, Gyeonggi-do (KR)

(72) Inventors: Kyu Jung CHO, Hwaseong-si (KR); Minji KIM, Suwon-si (KR)

(73) Assignee: INNO ROBOTICS INC., Hwaseong-si, Gyeonggi-do (KR)

(21) Appl. No.: 18/711,981

(22) PCT Filed: Nov. 29, 2022
(86) PCT No.: PCT/KR2022/019028

§ 371 Date: May 21, 2024

(30) Foreign Application Priority Data
Nov. 29, 2022 (KR) 10-2022-0162251

(51) Int. Cl. H10P 72/76

(52) U.S. Cl. CPC H10P 72/7624; H10P 72/7618

(57) ABSTRACT

A ZT stage as a ZT stage capable of vertical movement and rotational movement of a chuck placed on an upper portion includes: a base; a lifting module including a voice coil motor installed on an upper portion of the base; a gravity compensator installed on the upper portion of the base; a mover body formed on the upper portion of the base in a cylindrical shape, and having protrusions seated on the voice coil motor on a cylindrical outer peripheral surface, and connectors to which gravity compensators are fastened, respectively; a DD motor formed inside the mover body and guiding the rotational movement of the chuck; and a support mechanism transmitting rotational force of the DD motor to the chuck.

### TECHNICAL FIELD

The present disclosure relates to a ZT stage, and more particularly, to a ZT stage which is tiltable.

### BACKGROUND ART

In a device manufacturing process or a device measurement process, a table device having a table supporting a workpiece is used. The table device moves on the table and determines a position of the workpiece supported on the table. As disclosed in Patent Documents 1, 2, 3, and 4, a table device capable of moving on the table in three directions: an X-axis direction, a Y-axis direction, and a OZ direction (ZT direction) is known.

In general, a movable table device is a combination form of a ZT stage that can rotate while ascending and descending in the ZT direction on an XY stage which enables moving on planes in the X-axis direction and the Y-axis direction.

The movable table device performs precise processes such as processing or inspecting semiconductor wafers. In order to perform the precise process, a system controlling the stage is more important than anything else.

In particular, reducing the weight of the stage for precise control, improving system characteristics, and the like have recently become more important issues as start of mass production of 450 mm wafers has become a reality.

### DISCLOSURE

### Technical Problem

The present disclosure is directed to providing a ZT stage capable of precise position and posture controlling, and particularly, providing a ZT stage which is tiltable.

### Technical Solution

According to an exemplary embodiment to the present disclosure, a ZT stage as a ZT stage capable of vertical movement and rotational movement of a chuck placed on an upper portion includes: a base; a lifting module including a voice coil motor installed on an upper portion of the base; a gravity compensator installed on the upper portion of the base; a mover body formed on the upper portion of the base in a cylindrical shape, and having protrusions seated on the voice coil motor on a cylindrical outer peripheral surface, and connectors to which the gravity compensators are fastened, respectively; a DD motor formed inside the mover body and guiding the rotational movement of the chuck; and a support mechanism transmitting rotational force of the DD motor to the chuck, in which the lifting module includes a first support body connecting the voice coil motor to the base, a lifting housing connected to the voice coil motor and ascending or descending, a spherical bearing formed on an upper portion of the lifting housing, a pole fastened to the spherical bearing and connected to the protrusion of the mover body, a disk connected to an upper portion of the pole and fastened to the protrusion, and a fixation pin fastened to one end of the pole, and coupling the mover body and the pole.

As an exemplary embodiment, the lifting module further includes a second support body fixed to the base and guiding ascending or descending of the lifting housing, and a cross-roller guide attached to the lifting housing and the second support body, and guiding the movement of the lifting housing.

As an exemplary embodiment, the lifting module further includes an encoder measuring an ascending/descending position of the mover body, a scale attached to the lifting housing, and a third support body attached to the base and supporting the encoder.

As an exemplary embodiment, the gravity compensator includes an air cylinder formed on the upper portion of the base, a piston shaft fastened to the air cylinder and having one upper end coupled to the connector of the mover body, and a coupling pin fastened to the piston shaft and screw-coupled to the mover body.

As an exemplary embodiment, an air injection port formed in the base and injecting air into the air cylinder is formed.

As an exemplary embodiment, the base is made of aluminum, and a plurality of perforations is formed, which penetrates an upper surface and a lower surface of the base.

### Advantageous Effects

According to an exemplary embodiment of the present disclosure, a ZT stage is tiltable.

Further, precise position and posture control is possible, and precise measurement by a scale is possible.

Driving is easy by a comparatively light-weighted ZT stage, and precise processing of a workpiece is possible.

### DESCRIPTION OF DRAWINGS

FIG. 1 is a perspective view of a ZT stage according to an exemplary embodiment of the present disclosure.

FIG. 2 is a perspective view of a lifting member according to an exemplary embodiment of the present disclosure.

### MODES OF THE INVENTION

Specific structural or functional descriptions of exemplary embodiments according to the concept of the present disclosure disclosed in this specification are merely illustrative for the purpose of explaining the exemplary embodiments according to the concept of the present disclosure, and the exemplary embodiments according to the concept of the present disclosure may be implemented in various forms and are not limited to the exemplary embodiments described herein.

The embodiments of the concept of the present disclosure may have various modifications and various forms and specific exemplary embodiments will be illustrated in the drawings and described in detail in this specification or application. However, this does not limit the exemplary embodiment according to the concept of the present disclosure to specific exemplary embodiments, and the present disclosure covers all the modifications, equivalents and replacements included within the idea and technical scope of the present disclosure.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other expressions describing the relationship of the components, that is, expressions such as “between” and “directly between” or “adjacent to” and “directly adjacent to” should be similarly interpreted. Terms used in this specification are used only to describe specific exemplary embodiments and are not intended to limit the present disclosure. A singular form includes a plural form if there is no clearly opposite meaning in the context. In this specification, it should be understood that term “include” or “have”indicates that a feature, a number, a step, an operation, a component, a part or the combination thereof which are disclosed in this specification are present, but does not exclude a possibility of presence or addition of one or more other features, numbers, steps, operations, components, parts or combinations thereof, in advance.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined here.

Hereinafter, exemplary embodiments of the present disclosure will be described in detail with reference to the accompanying drawings. However, the scope of the patent application is not restricted or limited by exemplary embodiments. Like reference numerals illustrated in the respective drawings designate like members.

A ZT stage according to an exemplary embodiment of the present disclosure is a device mounted on a stage for measurement and inspection equipment used in a semiconductor process. Unlike the XY stage, which moves on a plane, the ZT stage is a stage that moves a workpiece placed on the stage up and down and rotates the workpiece around the Z axis. Further, the ZT stage according to an exemplary embodiment of the present disclosure is tiltable to tilt the workpiece or maintain flatness of the workpiece.

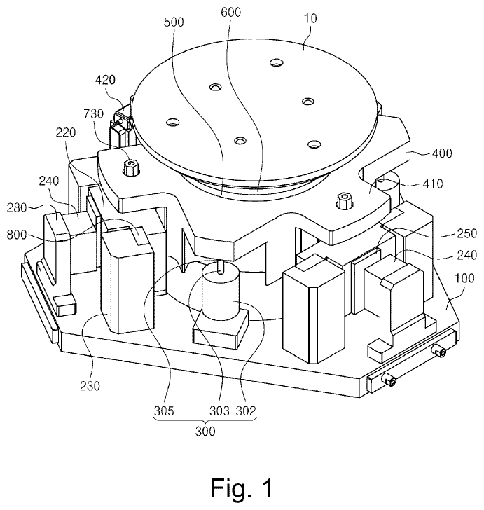

FIG. 1 is a perspective view of a ZT stage according to an exemplary embodiment of the present disclosure.

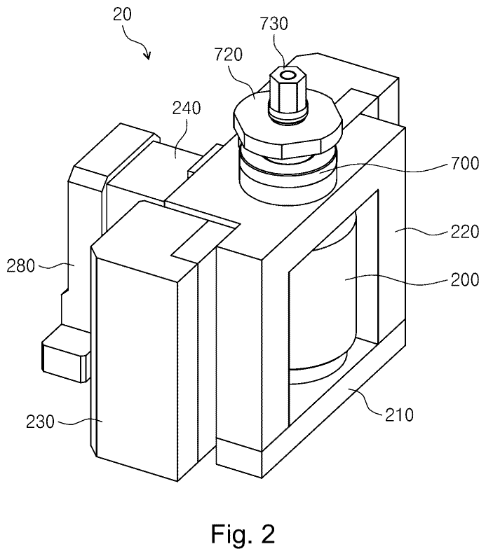

FIG. 2 is a perspective view of a lifting module according to an exemplary embodiment of the present disclosure.

As illustrated in FIGS. 1 and 2, the ZT stage according to an exemplary embodiment of the present disclosure, as a ZT stage capable of vertical and rotational movement of a chuck 10 placed on the top, includes a base 100, a lifting module 20 including a voice coil motor 200 installed on an upper portion of the base 100, gravity compensators 300 installed on the upper portion of the base 100, protrusions 410 formed on the upper portion of the base 100 in a cylindrical shape and seated on the voice coil motors 200 on a cylindrical outer peripheral surface, respectively, a mover body 400 having connectors 420 to which the gravity compensators 300 are fastened, respectively, a DD motor 500 formed inside the mover body 400 and guiding rotational movement of the chuck 10, and a support mechanism 600 transmitting the rotational force of the DD motor 500 to the chuck 10.

The lifting module 20 according to an exemplary embodiment of the present disclosure includes a first support body 210 connecting the voice coil motor 200 to the base 100, a lifting housing 220 being connected to the voice coil motor 200 and ascending or descending, a spherical bearing 700 formed on an upper portion of the lifting housing 220, a pole 710 fastened to the spherical bearing 700 and connected to the protrusion 410 of the mover body 400, a disk 720 connected to an upper portion of the pole 710 and fastened to the protrusion 410, and a fixation pin 730 fastened to one end of the pole 710 and coupling the mover body 400 and the pole 710.

The base 100 is placed on a lower portion of the ZT stage, and the voice coil motor 200 providing a thrust for vertical movement to be described below, the gravity compensator 300, etc., are firmly attached to an upper surface of the base 100. In order to install the components of the stage, a bolt fastening hole 110 may be formed, which penetrates the upper surface and a lower surface of the base 100.

The base 100 may be made of an aluminum material for light-weighting of the ZT stage, and a polygonal or circular perforation 120 may be formed on a plane on which the components of the stage are not installed so as to secure rigidity in transverse force, vertical force, etc., applied to the base 100. Furthermore, it is preferable that the perforations 120 formed in the base 100 are formed to be symmetric to each other based on a center point in order to maintain a balance for rotational force.

The voice coil motor 200 is installed on the upper portion of the base 100 described above. More specifically, the voice coil motor 200 may be connected to the base 100 via a first support body.

In the ZT stage according to an exemplary embodiment of the present disclosure, three voice coil motors 200 are installed to be symmetric to each other based on a center of the base 100. The voice coil motor 200 is a motor which is generally capable of precise linear movement, and a movable body in which a coil is wound on a central outer diameter having a three-dimensional shape with magnetic force is placed in the voice coil motor 200.

In the voice coil motor 200 according to an exemplary embodiment of the present disclosure, when current is applied to the coil, a mover body (not illustrated) wound with the coil ascends or descends by the magnetic force, therefore the voice coil motor 200 is a linear motor which may adjust an ascending or descending speed, an acceleration, etc., by a current value input into the coil.

Three voice coil motors 200 are seated on the protrusion 410 of the mover body 400 placed at the center of the ZT stage to allow the mover body 400 to ascend or descend. The mover body 400 is described below in detail.

The gravity compensator 300 is coupled and installed onto the upper portion of the base 100. In the ZT stage according to an exemplary embodiment of the present disclosure, three gravity compensators 300 are installed to be symmetric to each other based on the center of the base 100.

The gravity compensator 300 includes an air cylinder 302 formed on the upper portion of the base 100, a piston shaft 303 fastened to the air cylinder 302 and having one upper end coupled to the connector 420 of the mover body 400, and a coupling pin 305 fastened to the piston shaft 303 and screw-coupled to the mover body 400.

The air cylinder 302 performs a function of compensating a pressure applied by a weight of a processing member. A separate air injection port is provided on a lower portion of the air cylinder 302, so it is possible to adjust an air pressure.

The gravity compensator 300 compensates descending of the mover body 400 due to weights of components which repeatedly ascend and descend, such as the mover body 400 and the DD motor 500 mounted on the mover body 400 and a processing member such as a wafer mounted on the chuck 10.

Further, when the weight of the processing member mounted on the chuck 10 is not evenly distributed, a process may be conducted in a state in which the mover body 400 is tilted, but a balance of the processing member may be maintained through the gravity compensator 300.

The mover body 400 is a component which ascends and descends by the voice coil motor 200 in a cylindrical shape in which a lower portion is opened and a part of a center of an upper portion is opened. The DD motor 500 providing the rotational force is inserted into the mover body 400, and the support mechanism 600 on which the chuck 10 is seated is fastened to an upper portion of the DD motor 500.

Protrusions 410 seated on three voice coil motors 200, respectively and the connectors 300 to which three gravity compensators 300 are fastened, respectively are formed on an outer peripheral surface of the cylindrical mover body 400 according to an exemplary embodiment of the present disclosure.

The direct drive (DD) motor 500 as a device that provides the rotational force rotates without connection of a separate decelerator or gear. The DD motor 500 has a fixation part (not illustrated) having a disk-shaped cross section and a rotor in which the fixation part and the rotor (not illustrated) are connected through a bearing (not illustrated), and a stator and a permanent magnet (rotor) are provided on an outer side of the rotor, so when current is applied to the stator, a thrust generated by the magnetic force rotates the rotor.

The DD motor 500 as a precision control motor capable of resolutions of millions of steps per rotation may also adopt an encoder and a resolver according to a type.

The support mechanism 600 transmits the rotational force of the DD motor 500 to the chuck 10 on which the processing member is seated. The support mechanism 600 has a structure in which three arms 610 are connected to a circular center body 620. The support mechanism 600 may be a lightweight plastic or metallic material, but is not particularly limited thereto.

As illustrated in FIG. 2, the lifting module 20 which takes charge of tilting the ZT stage according to an exemplary embodiment of the present disclosure includes the first support body 210, the lifting housing 220, the spherical bearing 700, the pole 710, the disk 720, and the fixation pin 730. Further, the lifting module 20 includes a second support body 230 fixed to the base 100 and guiding ascending or descending of the lifting housing 230, and a cross-roller guide 800 attached to the lifting housing 220 and the second support body 230, and guiding movement of the lifting housing. The first support body 210 connects the voice coil motor 200 to the base 100. Specifically, the stator of the voice coil motor 200 may be fixed to the first support body 210. The first support body 210 is firmly coupled to the base 100 to prevent the movement of the voice coil motor 200.

The lifting housing 220 is connected to the voice coil motor 200. As illustrated in FIG. 2, the lifting housing 220 is positioned to surround the voice coil motor 200 at both sides and is connected to an upper end of the voice coil motor 200, thereby moving jointly when a mover of the voice coil motor 200 ascends or descends. The spherical bearing 700 is formed on the upper portion of the lifting housing 220. More specifically, a center of the spherical bearing 700 is connected to a line on which the upper portion of the voice coil motor 200 and the lifting housing 220 are connected. A circular fastening groove (not illustrated) is formed inside the spherical bearing 700 and multiple circular bearings (not illustrated) are formed therearound to allow a pole (not illustrated) to be described below which is fastened to the fastening groove to move as if drawing an arc.

The pole (not illustrated) fastened to the circular fastening groove formed at the center of the spherical bearing 700, which has a gourd bottle, may be constituted by one end having a spherical shape and the other end having a pole shape, but is not particularly limited thereto.

The disk 720 is connected to an upper portion of the pole and fastened to the protrusion 410. More specifically, the disk 720 is inserted into a disk groove (not illustrated) formed at the protrusion 410, and coupled to the mover body 400 jointly with the pole. Further, the pole and the mover body 400 are fixed by the fixation pin 730. The disk 720 is formed to pivot around a Z axis, and filters rotational noise in a yaw direction according to the ascending or descending of the voice coil motor 200 to prevent the rotation noise from being transmitted to the mover body 400.

As illustrated in FIG. 2, as the spherical bearing 700 is formed on the upper portion of the voice coil motor 200, when the voice coil motor 200 ascends or descends, the spherical bearing 700 is guided not to perform Z-axis movement, but arc movement by the pole.

Specifically, when 3-axis voice coil motors 200 ascend at the same height, the mover body 400 ascends on the Z axis. However, when the 3-axis voice coil motors 200 ascend at different heights or ascending and descending operations are simultaneously guided, the mover body 400 cannot but be tilted based on a central axis, but the pole 710 performs the arc movement upon tilting, so deformation of the mover body 400 does not occur, but precise control is possible.

The second support body 230 is made of the same material as the first support body 210, is fixed to the base 100, and guides the ascending or descending of the lifting housing 220. The second support body 230 according to an exemplary embodiment of the present disclosure is installed at both sides of the lifting housing 220, one dedicated rail of two dedicated rails of a cross-roller guide 800 is attached to the lifting housing 220 in a longitudinal direction, and the other remaining dedicated rail is installed at a location corresponding to the dedicated rail installed in the lifting housing in the second support body 230 to guide the lifting housing 230 to move along the Z axis when the lifting housing 230 ascends or descends.

In the cross-roller guide 800, two dedicated rails are connected to be parallel to each other, and the cross-roller guide 800 is constituted by a roller (or ball) and a roller cage (or ball cage) between the dedicated rails. In particular, the cross-roller guide 800 may respond to loads in up, down, left, and right directions, and a preliminary pressure may be simply assigned, so there is no clearance and rigidity is large.

The ZT stage according to an exemplary embodiment of the present disclosure includes an encoder 240 measuring an ascending or descending location of the mover body 400, a scale 250 attached to the lifting housing, and a third support body 280 attached to the base 100 and supporting the encoder 240.

As illustrated in FIG. 3, the encoder 240 is installed toward one surface of the lifting housing 220 and measures an ascending or descending location of the lifting housing 220. The encoder 240 according to an exemplary embodiment of the present disclosure may be an optical encoder or a magnetic encoder, and two types of encoders have the same principle in that feedback is provided from a physical environment, but the optical encoder may be distinguished from the magnetic encoder in that a physical signal for the feedback is light.

The encoder 240 according to an exemplary embodiment of the present disclosure outputs movement as an electric signal which may be read by a counter or a control device with location and speed information of the lifting housing 220 which moves linearly on the Z axis.

The encoder 240 is a sensor device required for feeding back and controlling a location of a precision stage, and the encoder 240 according to an exemplary embodiment of the present disclosure may also calculate a position by a scheme of counting a pulse signal which is an optical signal reflected by irradiating light to a scale 250 in which two rows of slits are arranged in a line.

The scale 250 is attached to the lifting housing 220, and installed at a position mutually corresponding to the encoder 240.

The encoder 240 is fixed and installed into the third support body 280 attached and fixed to the base 100.

The scale 250 according to an exemplary embodiment of the present disclosure is attached to the lifting housing 220, so even when the mover body 400 is actually tilted, distortion of the scale 250 does not occur, a tilting angle at which the mover body 400 is tilted may be accurately calculated.

The present disclosure has been described with reference to the exemplary embodiment illustrated in the drawings, but this is just exemplary, and it will be appreciated by those skilled in the art that various modifications and other exemplary embodiments equivalent thereto can be made therefrom. For example, the described techniques are performed in a different order from the described method, and/or components such as a system, structure, device, circuit, etc., described are collected or combined in a form different from the described method, or even if the components are replaced or substituted by other components or an equivalent, an appropriate result can be achieved. Accordingly, the true technical scope of the present disclosure should be defined by the technical spirit of the appended claims.

1. A ZT stage capable of vertical movement and rotational movement of a chuck placed on an upper portion, comprising:
a base;
a lifting module including a voice coil motor installed on an upper portion of the base;
a gravity compensator installed on the upper portion of the base;
a mover body formed on the upper portion of the base in a cylindrical shape, and having protrusions seated on the voice coil motors on a cylindrical outer peripheral surface, respectively, and connectors to which gravity compensators are fastened, respectively;
a DD motor formed inside the mover body and guiding the rotational movement of the chuck; and
a support mechanism transmitting rotational force of the DD motor to the chuck,
wherein the lifting module includes
a first support body connecting the voice coil motor to the base,
a lifting housing connected to the voice coil motor and ascending or descending,
a spherical bearing formed on an upper portion of the lifting housing,
a pole fastened to the spherical bearing and connected to the protrusion of the mover body,
a disk connected to an upper portion of the pole and fastened to the protrusion, and
a fixation pin fastened to one end of the pole, and coupling the mover body and the pole.

2. The ZT stage of claim 1, wherein the lifting module further includes
a second support body fixed to the base and guiding ascending or descending of the lifting housing, and
a cross-roller guide attached to the lifting housing and the second support body, and guiding movement of the lifting housing.

3. The ZT stage of claim 2, wherein the lifting module further includes
an encoder measuring an ascending/descending position of the mover body,
a scale attached to the lifting housing, and
a third support body attached to the base and supporting the encoder.

4. The ZT stage of claim 1, wherein the gravity compensator includes
an air cylinder formed on the upper portion of the base,
a piston shaft fastened to the air cylinder and having one upper end coupled to the connector of the mover body, and
a coupling pin fastened to the piston shaft and screw-coupled to the mover body.

5. The ZT stage of claim 4, wherein an air injection port formed in the base and injecting air into the air cylinder is formed.

6. The ZT stage of claim 1, wherein the base is made of aluminum, and a plurality of perforations is formed, which penetrates an upper surface and a lower surface of the base.
